(19) United States
(12) Patent Application Publication
(10) Pub. No.: US 2006/0061369 A1
(43) Pub. Date: Mar. 23, 2006

(54) Information handling system integrated cable tester

(76) Inventors: Kevin T. Marks, Round Rock, TX (US); Farzad Khosrowpour, Pflugerville, TX (US)

Correspondence Address: HAMILTON & TERRILE, LLP, P.O. BOX 203518, AUSTIN, TX, 78720, US

(21) Appl. No.: 10/945,716

(22) Filed: Sep. 20, 2004

(51) Int. Cl. G01R 31/02

(52) U.S. Cl. 324/542

(57) ABSTRACT

An integrated cable tester detects cable faults by coupling a single cable to host and expander connectors of an interface module and determining whether each of plural ports of the connectors has an associated PHY Ready signal. An LED interfaced with the cable tester illuminates to indicate a normal cable and fails to illuminate if the cable tests faulty. In one embodiment a module tester determines whether the module has degraded performance when a single cable is detected as coupled to the host and expander connectors of the module. The module tester clears the interface module's error log and initiates a reset of communication between the host and expander ports. Upon completion of the reset, such as detection of all PHY Ready signals for the plural ports, the module tester reads the error log and indicates errors as degrading the performance of the interface module.

### BACKGROUND OF THE INVENTION

1. Field of the Invention

The present invention relates in general to the field of testing information handling system cable connections, and more particularly to a system and method for integrated testing of cable connections between host and expansion ports.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As businesses and individuals have come to increasingly rely on information handling systems, industry has focused greater attention on developing and implementing cost effective and reliable systems for storing information. Some considerations in the design of information storage systems include redundancy to ensure that stored information is not lost and scalability to allow the addition of more storage as the amount of stored information fills available capacity. A basic information handling system design that provides both access redundancy and scalability is the JBOD design, short for “Just a Bunch Of Discs.” In a JBOD design, a series of hard disc drive storage devices store information under the control of a host Serial Attached SCSI (SAS) controller, such as with a HBA or RAID configuration. SAS is a point-to-point architecture that uses expanders to fanout to communicate with multiple devices. The SAS standard defines “phy” device objects to support interfaces with other devices, and typical SAS devices have ports with plural associated phys. Each phy consists of a transceiver with a transmit and receive pair and associated PHY Layer SP state machine. Typically, a PHY state machine that completes initialization testing outputs a PHY_Ready signal to indicate that the phy is in a ready state and communicating with a phy of another device which may be over a SAS cable. The hard disc drives communicate over a common backplane and through SAS InterFace Module (SIF) cards, each SIF card having a plural of SAS expanders, a host port to connect to either the host SAS controller or the expansion port of a previous JBOD in a daisy chain configuration and also having an expansion port to cascade to additional JBODs. A JBOD information handling system scales to store additional information by interfacing the host port of an SIF expansion card to the SAS controller of a first JBOD configuration and interfacing the expansion port of the SIF card to the host port of another SIF card associated with a second JBOD configuration. The interface between the expansion port of the first SIF card and the host port of the second SIF card is generally made through a separate external cable.

One difficulty with a JBOD information handling system is that system failures are often difficult to identify, track down and fix. For instance, a failure associated with communicating with a hard disc drive might originate with the hard disc drive itself, one of the SIF cards in a daisy chain configuration that support communication with the hard disc drive, or one of the cables that interface between host and expansion ports of the SIF cards. Perhaps the failure that presents the greatest nuisance is the failure of a cable since cables are generally inexpensive and reliable so that isolating a cable failure is often one of the last troubleshooting steps. Generally, to test a cable the existing cable is swapped with a different cable to see if the same problems continue to exist. However, swapping out cables is time consuming and often inconclusive, such as where a batch of cables has the same production fault leading to repeated failures. Further, even though a JBOD information handling system establishes communication through a cable, the quality of the communication is sometimes degraded due to minor malfunctions in the SIF card or cable interface. For instance, disparity, CRC and reset problems associated with the SAS link between the SAS controller and SIF card or between SIF cards on separate JBODs are typically managed by SAS controller logic, albeit with generally degraded performance. Identification and correction of such problems typically involves interaction through the SAS controller to read error logs maintained by the SAS expanders on the SIF cards. These diagnostic steps are often difficult to explain in a telephone conversation, such as when a customer calls for service from an information handling system manufacturer due to a JBOD information handling system failure.

### SUMMARY OF THE INVENTION

Therefore a need has arisen for a system and method which integrates testing of the cable and interfaces between JBOD devices.

In accordance with the present invention, a system and method are provided which substantially reduce the disadvantages and problems associated with previous methods and systems for testing cable interfaces. A cable coupled to the host and expansion ports of an interface module tests normal if port Phy Ready signal is asserted at each port. Normal or degraded communication of information over the cable is tested by determining if errors occur during a reset sequence across the physical cable link to assert the port Phy Ready signal. If errors occur with all ports having an associated Phy Ready Signal, then a normal cable is indicated while degraded communication shown by the errors indicate a bad interface module.

More specifically, a cable tester integrated in a SIF module card interfaces with each Phy Ready signal associated with the phys of each port in a SAS external cable to provide a visual indication of whether the cable is in a normal or failed/degraded state. For instance, the cable tester is an AND gate interfaced with the Phy Ready signal of each phy pin of the expansion ports of an expansion connector and with an LED. The AND gate illuminates the LED if each Phy Ready signal from each phy of the expansion port is asserted at each port thus confirming that cable has successfully initiated communication between an expansion and host port. Integrated cable testing is provided by coupling the cable in a test configuration with one end of the cable coupled to the expansion connector and the other end of the cable to the host connector of the same SIF module card. A module tester integrated in the SIF module card detects the cable test configuration by analyzing the address information exchanged in the IDENTIFY frame after the reset sequence and initiates a test for degraded operations of the cable and interfaces of the SIF module card. Error logs associated with the phys of each port are cleared and a reset sequence is initiated for phys in the host and expansion ports of the SIF module card. If incremental errors are logged in the phy error counters during the reset sequence, a visual indication of degraded operations is provided by one or more LEDs.

The present invention provides a number of important technical advantages. One example of an important technical advantage is that interfacing a cable between a host and expansion port of a SIF card provides a simple and accurate test of cable operability. A cable failure is quickly isolated by the illumination of a LED light where the SIF card fails to establish communication between the phys of the host and expansion ports due to one or more of the phys not reaching the Phy Ready state in the PHY Layer state machine. If the cable tests good in that all phys communicate, degraded performance of the SIF card is rapidly identified by LED illumination to effectively isolate the difficulty to a particular SIF card. Rapid and accurate troubleshooting with a simple cable connection reduces the complexity associated with identifying correcting a JBOD failure in the field through a telephone description of the procedure by a manufacturer representative to a customer, thus providing reduced service expense and an improved customer experience when difficulties do arise.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of JBOD information handling systems daisy chained with SAS interface modules and external SAS cables;

FIG. 2 depicts a block diagram of a SAS interface module having an integrated cable tester and module tester; and

FIG. 3 depicts a flow diagram of a process for integrated cable and module testing of a SAS interface module.

### DETAILED DESCRIPTION

Integrated testing of SAS external cables is performed by coupling a cable to both the host and expansion connectors of an SAS interface module (SIF) for interfacing with a JBOD information handling system and indicating a cable good or normal if each phy of each port of the connectors achieves the Phy Ready state thereby driving the Phy Ready signal. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

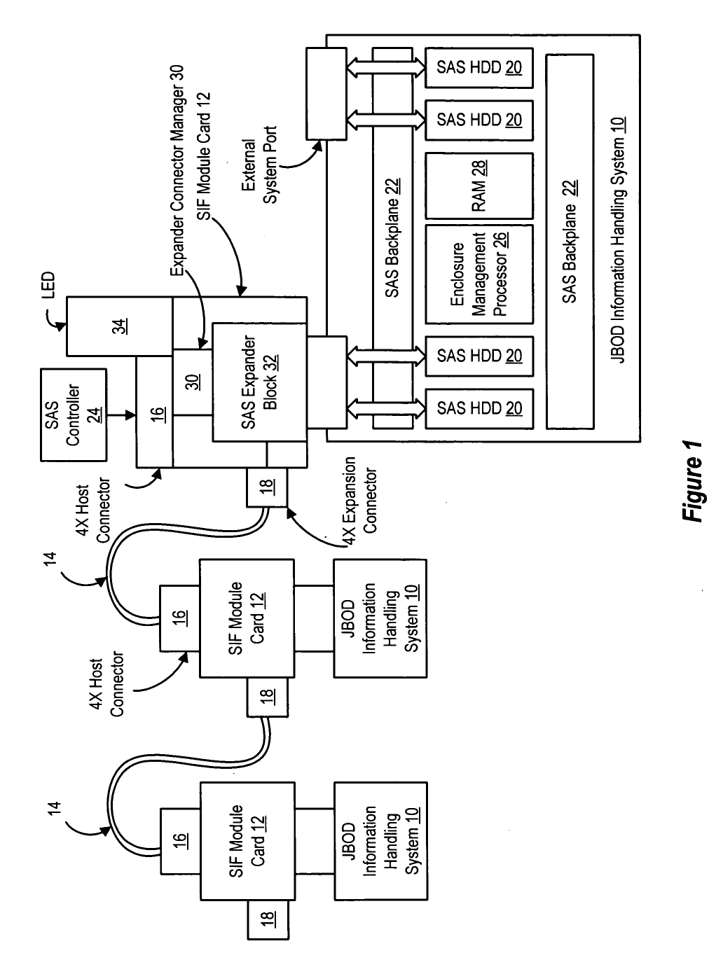

Referring now to FIG. 1, a block diagram depicts plural JBOD information handling systems 10 daisy chained with SAS interface module (SIF) cards 12 and external SAS cables 14. Each SIF card 12 associated with JBOD information handling system 10 has two sets of ports, a first set of host ports associated with a host connector 16 and a second set of expansion ports associated with an expansion connector 18. Host ports associated with host connector 16 interface with a host SAS controller, such as in a HBA or RAID configuration, or, alternatively interfaces with expansion ports associated with an expansion connector of another SIF card 12. As depicted by FIG. 1, the expansion ports of expansion connector 18 cascades to other JBOD information handling systems through host ports of host connectors 16 in a daisy chain configuration with information communicated through SAS external cables 14. For instance, an SAS external cable couples from an expansion connector 18 to a host connector 16 with four separate phys for communication of information over four separate links. The four phys or links form a port, known as a 4X port. Each JBOD information handling system 10 includes plural SAS hard disc drives 20 that store information communicated over a SAS backplane 22 under the direction of an SAS controller 24 of host connector 16. The JBOD information handling systems also include conventional processing components for processing information, such as a enclosure management processor 26 and RAM 28.

Although not required by the SAS standard, each phy on a SAS expander typically includes a pin to communicate when the phy is in a PHY Ready state in the PHY Layer state machine associated with the port is ready to communicate information. The PHY Ready is asserted on each Phy after completion of the COMINIT/COMSAS link reset procedure, the calibration sequence to perform speed negotiation, Dword synchronization, and exchange of the IDENTIFY frame information with the attached phy in the other port. These procedures are managed by the PHY Layer state machine. An expander connector manager 30, such as a microcontroller, coordinates the operations of a SAS expander block 32 looks at IDENTIFY frame information to detect and identify connecting phys in the ports. SAS expander block 32 includes logic that detects the state of the Phy Ready signal of each phy in the port of the host connector 16 and illuminates an LED 34 with a first configuration, such as a solid color, if each phy in the port asserts a PHY Ready signal, and illuminates LED 34 with a second configuration, such as a flashing color, if one or more phy ports fails to assert the PHY Ready signal. An external SAS cable 14 is tested by connecting one end of the cable to a host connector and the other end of the cable to the expander connector of the same SIF module card 12. If Phy Ready is asserted for each phy in the port, then LED 34 indicates the cable tests normal or good, and if one or more Phy Ready signals fails to assert, then LED 34 indicates a possible cable failure by not illuminating or flashing. Cable failure is confirmed by either verifying the proper operation of SIF module card 12 with another cable or testing the same cable on a different SIF module card 12.

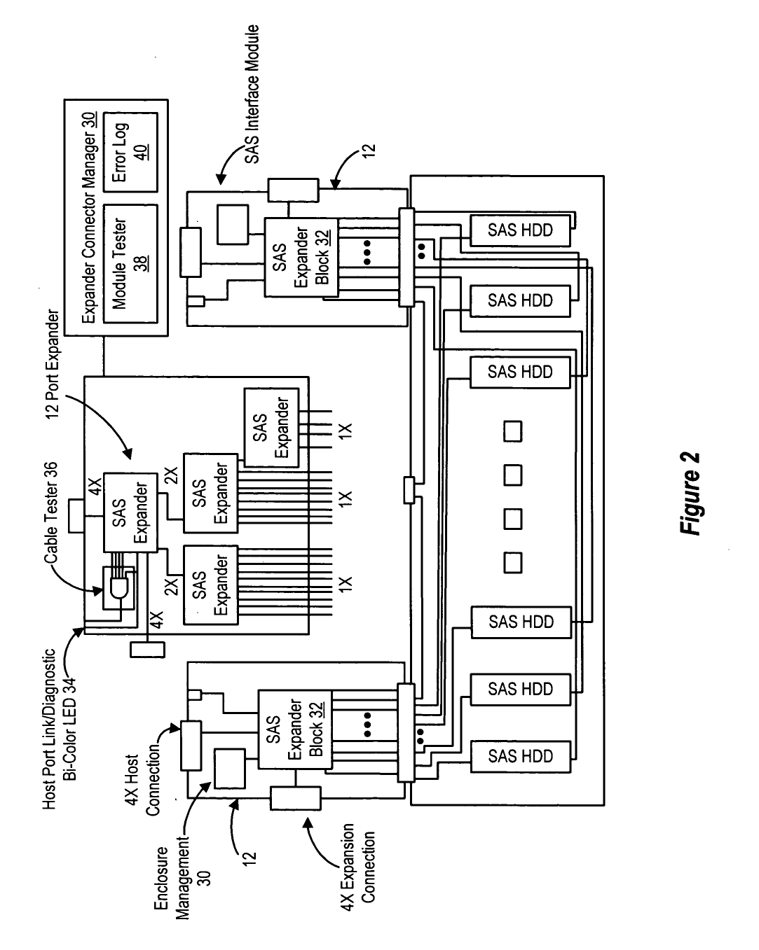

Referring now to FIG. 2, a block diagram depicts a 12 port SAS expander block 32 within a SAS InterFace module card 12 having an integrated cable tester 36 and module tester 38. Cable tester 36 is an AND gate interfaced with the Phy Ready signal (pin) of each phy in the host port so that a bi-colored LED illuminates if all PHY Ready signals are asserted. A normal or good cable in a cable test configuration, i.e., having each end interfaced to the host and expander connectors of a single SIF module card, will illuminate the LED as long as all phys in the port supported by the cable communicate information. A normal or good cable in an operational daisy chained configuration will also illuminate the LED since all PHY Ready signals are asserted. Illumination of the LED indicates normal cable operations, but does not necessarily mean that the communication of information is free from errors. For instance, even though all phys in the port communicate information, one or more phys may communicate information in a degraded mode due to errors in the operation of SIF module card 12 or other factors such as noise or signal integrity. Degraded modes allow communication of information at reduced rates in the presence of disparity, CRC and reset problems.

In order to verify normal operations of a SIF module card 12, a module tester 38 associated with expander connector manager 30 checks for degraded operations due to errors, such as disparity, CRC and reset errors. Module tester 38 is, for instance, firmware instructions that run on expander connector manager 30 when a cable test configuration is detected. A cable test configuration is detected if the addresses received in the IDENTIFY frame by the phys of the host port are the same as the address on the phys of the expander port since both the host and expander ports are associated with the same expander on the SIF module card and thus have the same SAS address with different Phy identifiers. Upon detection of the cable test configuration, module tester 38 clears the error log 40 associated with each phy in the port and initiates a Phy/Link reset sequence. Error log 40 is associated with each Phy in expander block 32 and is incremented when errors occur, such as CRC, disparity, loss of Dword synchronization and reset count errors. Upon initiation of the reset sequence, error log 40 is set to zero and the normal initialization diagnostic routine associated with reset of each phy runs to bring each port back to the PHY Ready state. If module tester 38 detects that no error logs are incremented after each port's phys are PHY Ready, then SIF module card 12 is not operating in a degrade mode. If error log 40 is incremented, then a degraded mode is detected. As an additional test, a data stream is communicated between the host and expander ports in the cable test configuration and error log 40 is checked for incremental error counts that indicate operation in a degraded mode. The presence or absence of errors and the type of errors are indicated through a bi-colored LED 34 such as by driving an appropriate GPIO pin. For instance, having the LED off indicates a connection problem with at least one PHY Ready signal inactive, having a red LED indicates a normal cable but the presence of data errors associated with a degraded mode of operations, and a green LED indicates normal operations. In one alternative embodiment, flashing LEDs or other LED configurations may be used to identify the type of data errors or degraded mode.

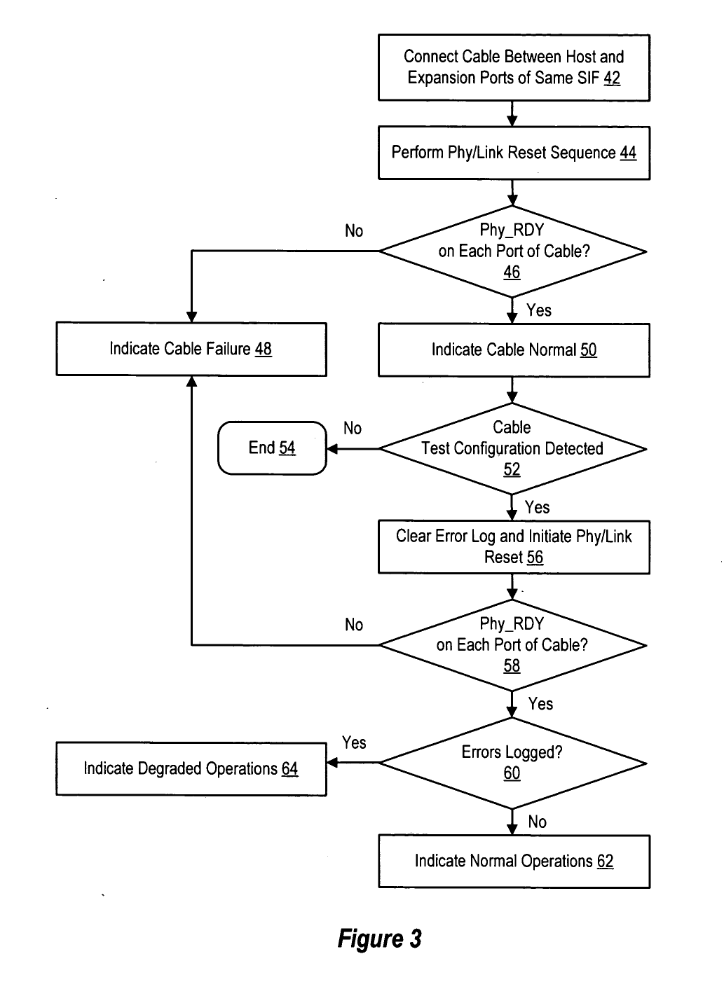

Referring now to FIG. 3, a flow diagram depicts a process for integrated cable and module testing of a SAS InterFace module for a JBOD information handling system. The process begins at step 42 with the coupling of a cable for test in a test configuration between the host and expansion ports of the same SIF module card. At step 44, the SIF module card automatically performs a Phy/Link reset procedure on each phy in the port to bring the state machine to the PHY Ready state and to assert the PHY Ready signal. The PHY Ready state signal indicates that the state machine has completed the COMINIT/COMSAS link reset procedure, the calibration sequence to set speed negotiations, Dword synchronization, and exchange of the associated IDENTFY frame with the attached phy. At step 46 a determination is made of whether each phys PHY Ready signal in the port is asserted. If a phy in a port lacks a PHY Ready signal, the process ends at step 48 with an indication of a failed cable test, suggesting that either the cable or the SIF module card is inoperable. If all phys in a port assert the PHY Ready signal, the process continues to step 50 to indicate a normal cable.

Once the cable tests normal at step 50, the process continues to step 52 to determine whether the SIF module card is operating in a degraded mode. At step 52, a determination is made that the cable is coupled in the test configuration by determining that the address returned by the phys in the host port to the phys in the expansion ports in the IDENTIFY frame are the same as the address of the phys in the expansion port. Each phy on an expander in the expander block has the same address with a different Phy identifier. At step 56, the error log associated with each phy is cleared and a Phy/Link reset is initiated. The phy error log increments when errors occur, such as CRC, disparity, loss of Dword synchronization and reset count errors. By clearing the error log, the detection of errors during the reset sequence is made by determining if the error log has incremented from zero after the reset sequence completes. At step 58, a determination is made that the reset sequence has completed by detecting a PHY Ready signal associated with each phy in the port. At step 60, if the error log has incremented, the process continues to step 64 to indicate degraded operations. If at step 60 the error log has not incremented, the process continues to step 62 to indicate normal operations. In addition to performing the reset sequence, a data stream may be communicated through each phy in the port before checking the error log to determine if errors arise related to information communication.

Although the present invention has been described in detail, it should be understood that various changes, substitutions and alterations can be made hereto without departing from the spirit and scope of the invention as defined by the appended claims.

What is claimed is:

1. A system for testing a cable that interfaces a host connector of a first module to an expansion connector of a second module, the module having both a host and an expansion connector, each connector having plural device ports, each port having a phy, the system comprising:
an expander block associated with the module and operable to interface plural devices with the host and expansion connector device ports, each port having information signals operable to communicate information and a PHY Ready signal operable to signal that the phy of each information port is operational to communicate information;
a cable tester interfaced with PHY Ready signal, the cable tester operable to detect a normal state if a PHY Ready signal is asserted by each phy of the ports with a cable in a cable test configuration, the test configuration having the cable interfaced between the host and expansion connectors of the module, the cable tester further operable to detect a fault state if one or more PHY Ready signals are not asserted in the cable test configuration; and
an indicator interfaced with the cable tester and operable to indicate the state of the cable tester.

2. The system of claim 1 wherein the module comprises an interface module for interfacing JBOD devices.

3. The system of claim 2 wherein the module comprises a Serial Attached SCSI Interface Module card.

4. The system of claim 1 further comprising:
a module manager operable to manage communication of information through the module and to track communication errors with an error log; and
a module tester interfaced with the expander block and the module manager, the module tester operable to detect a cable in the test configuration, to reset the error log, to initiate a reset between the host and expansion ports, to indicate a normal state if no errors are logged in the error log after the reset, and to indicate a fault state if one or more errors are logged in the error log after the reset.

5. The system of claim 4 wherein the indicator is further operable to indicate a cable fault with a first indication and to indicate an error log fault with a second indication.

6. The system of claim 5 wherein the indicator comprises one or more LEDs.

7. The system of claim 5 wherein the error log faults comprise disparity, CRC or reset faults associated with one or more phys.

8. The system of claim 4 wherein the module manager comprises a processor for port connection setup and management, and the module tester comprises firmware associated with the processor, the firmware storing instructions to reset the error log and initiate a reset between the host and expansion ports.

9. A method for testing an information handling system cable, the cable having plural host to expansion port interfaces, the method comprising:
coupling the cable to a host and expansion connector of an interface module;
executing initiation of communication between a host port and expansion port of the interface module through the cable, each port having plural phys;
providing a visual indication of a normal state at the interface module if each phy of the ports have an associated PHY Ready signal; and
providing a visual indication of a failed cable if one or more phys in a port fail to have an associated PHY Ready signal.

10. The method of claim 9 wherein the module comprises a SIF and executing initiation comprises performing link reset, calibration, speed negotiation Dword synchronization and identity frame exchange between each host and expansion port to assert the PHY Ready signal at the host port.

11. The method claim 9 wherein providing a visual indication of a normal state comprises illumination of one or more LEDs with a first indication.

12. The method of claim 9 further comprising:
detecting that the cable couples to the host and expansion connectors of the interface module, the module having an error log;
clearing the error log of the module;
initiating a link reset sequence between the host and expansion port;
detecting a PHY Ready signal associated with each phy of the ports; and
determining degraded performance associated with the interface module if an error is logged in the error log.

13. The method of claim 12 wherein the interface module comprises a Serial Attached SCSI interface module and the error comprises one or more of a disparity, CRC or reset error.

14. The method of claim 12 further comprising:
providing a visual indication of degraded interface module performance.

15. The method of claim 14 wherein:
providing a visual indication of a failed cable further comprises illuminating one or more LEDs in a first indication; and
providing a visual indication of degraded interface module performance comprises illuminating one or more LEDs in a second indication.

16. The method of claim 12 wherein detecting that the cable couples to the host and expansion connectors of the interface module further comprises detecting at the interface module that the host and expansion port identification information are each associated with the interface module.

17. An information handling system comprising:
plural hard disc drives interfaced through an SAS backplane;
a host SAS controller interfaced with the hard disc drives and the SAS backplane, the host SAS controller operable to coordinate the communication of information over the SAS backplane;
a SAS interface module interfaced having a SAS expander block, a host connector port and an expander connector port, the expander block operable to interface plural phys of the host connector port and plural phys of the expander connector port with the SAS backplane, each port operable to communicate a PHY Ready signal associated with each phy;
a cable having host and expander connectors operable to couple with the interface module host and expander connector ports; and
a cable tester interfaced with the physical ready signals and operable to provide a normal status indication if each PHY Ready signal communicates through the cable coupled between the host and expander connector ports.

18. The information handling system of claim 17 further comprising an LED interfaced with the cable tester and operable to illuminate a normal indication.

19. The information handling system of claim 17 wherein the SAS interface module further has a module manager operable to maintain an error log and a module tester, the module tester operable to detect a single cable coupled to the host and expander connector ports, to clear the error log, to reset the expander block and to detect errors logged during the expander block reset.

20. The information handling system of claim 19 wherein each phy in the port has associated identifier information and wherein the module tester detects a single cable by comparing the identification information.
